(19) United States
(12) Patent Application Publication
(10) Pub. No.: US 2009/0184749 A1
(43) Pub. Date: Jul. 23, 2009

(54) HIGH-RESOLUTION DIGITALLY CONTROLLED TUNING CIRCUIT ELEMENTS

(75) Inventor: Hong-Yean Hsieh, Santa Clara, CA (US)

Correspondence Address: OKAMOTO & BENEDICTO, LLP, P.O. BOX 641330, SAN JOSE, CA, 95164, US

(73) Assignee: Realtek Semiconductor Corporation, Hsinchu (TW)

(21) Appl. No.: 12/106,945

(22) Filed: Apr. 21, 2008

Related U.S. Application Data
(60) Provisional application No. 61/021,882, filed on Jan. 17, 2008.

(51) Int. Cl. H03H 17/00

(52) U.S. Cl. 327/524

(57) ABSTRACT

A tuning circuit element for a tuning circuit. The tuning circuit element may include sub-elements for generating circuit values depending on logical values of digital control input signals. The tuning circuit element may be implemented with varactors, current sources, and other components or circuits. The tuning circuit element may be configured to have fine tuning resolution that is not necessarily limited by minimum feature size of a given fabrication process technology.

### CROSS-REFERENCE TO RELATED APPLICATION

This application claims the benefit of U.S. Provisional Application No. 61/021,882, filed on Jan. 17, 2008, entitled “High-Resolution Digitally Tuned Circuit And Method Thereof,” which is incorporated herein by reference in its entirety.

### BACKGROUND OF THE INVENTION

1. Field of the Invention

The present invention relates generally to electrical circuits, and more particularly but not exclusively to circuit elements for digitally tuned circuits fabricated as part of monolithic integrated circuits.

2. Description of the Background Art

Digitally tuned circuits are employed in a wide variety of applications involving data and voice communications. For portability, reliability, cost and other reasons, digitally tuned circuits are preferably fabricated as part of a monolithic integrated circuit (IC). Digitally tuned circuits typically include a variety of tuning circuit elements comprising capacitors, inductors, and the like for adjusting frequencies.

The minimum value of a particular circuit element that may be realized in a monolithic IC is determined by the minimum feature size allowable by the fabrication process technology (e.g., CMOS, BIPOLAR). However, the minimum feature size allowable by currently available process technology is usually limited by the precision of lithographic and etching processes employed in the fabrication. When a circuit element is used as a digitally controlled tuning circuit element of a communication system, the tuning resolution of the system is limited by the minimum value of the tuning circuit element. In other words, the minimum feature size of conventional digitally controlled tuning circuit elements limits tuning resolution.

“A Digitally Controlled Oscillator in a 90 nm Digital CMOS Process for Mobile Phones Bipolar,” by R. Staszewski et al. in IEEE Journal of Solid State Circuits, November 2005, pp 2203-2211, discloses a group of 50 aF capacitors employed as tuning circuit elements and fabricated using a 90 nm digital CMOS process. Even with a 90 nm CMOS process, the resulting tuning resolution is still too coarse for high-performance applications. What is needed is an even higher resolution digitally controlled tuning circuit element.

### SUMMARY

In one embodiment, a tuning circuit element includes sub-elements comprising a first circuit element and a second circuit element. The first and second circuit elements may comprise an electrical circuit or component. For example, the first and second circuit elements may comprise varactors or current sources. The first circuit element may be configured to receive a first digital control input signal, while the second circuit element may be configured to receive a second digital control input signal. The first and second digital control input signals are binary and complementary with each other.

The first circuit element may be configured to generate a first circuit value when the first digital control input signal is at a first logical value (e.g., binary one) and a second circuit value when the first digital control input signal is at a second logical value (e.g., binary zero), the first and second logical values being binary and complementary with each other. The second circuit element may be configured to generate a third circuit value when the second digital control input signal is at the first logical value and a fourth circuit value when the second digital control input signal is at the second logical value. The sum of the first and fourth circuit values is different from the sum of the second and third circuit values.

A combination of the first and fourth circuit values may be provided as a first output across nodes of the tuning circuit element. A combination of the second and third circuit values may be provided as a second output across the nodes of the tuning circuit element. The first output but not the second output may be provided to a tuning circuit to adjust a frequency when the first digital control input signal is at the first logical value. The second output but not the first output may be provided to the tuning circuit to adjust the frequency when the first digital control input signal is at the second logical value.

The first and second digital control input signals may be generated by a binary-to-thermometer decoder or a mismatch shaping circuit, for example. The input to the binary-to-thermometer decoder may comprise a binary coded signal generated by a sigma-delta modulator.

In one embodiment, a method performed by a tuning circuit element in a monolithic integrated circuit comprises: (a) receiving a first digital control input signal and a second digital control input signal, the first and second digital control input signals being binary and complementary with each other; (b) generating a first circuit value and a fourth circuit value when the first digital control input signal is at a first logical value, the first circuit value being generated by a first type of circuit element receiving the first digital control input signal, the fourth circuit value being generated by a second type of circuit element receiving the second digital control input signal, the first circuit value and the fourth circuit value being combined as a first output; (c) generating a second circuit value and a third circuit value when the second digital control input signal is at the first logical value, the second circuit value being generated by the first type of circuit element receiving the first digital control input signal, the third circuit value being generated by the second type of circuit element receiving the second digital control input signal, wherein a sum of the first circuit value and the fourth circuit value is different from a sum of the second circuit value and the third circuit value, the second circuit value and the third circuit value being combined as a second output; (d) providing the first output but not the second output to a tuning circuit in the monolithic integrated circuit when the first digital control input signal is at the first logical value; and (e) providing the second output but not the first output to the tuning circuit when the first digital control input signal is at a second logical value, the first and second logical values being binary and complementary with each other.

These and other features of the present invention will be readily apparent to persons of ordinary skill in the art upon reading the entirety of this disclosure, which includes the accompanying drawings and claims.

### DESCRIPTION OF THE DRAWINGS

FIG. 1 schematically shows a monolithic integrated circuit in accordance with an embodiment of the present invention.

FIG. 2 schematically shows a tuning circuit element in accordance with an embodiment of the present invention.

FIG. 3 schematically shows a tuning circuit element where circuit elements are coupled in parallel.

FIG. 4 schematically shows a tuning circuit element where circuit elements are coupled in series.

FIG. 5 schematically illustrates generation of control input signals for a tuning circuit element in accordance with an embodiment of the present invention.

FIG. 6 schematically illustrates generation of control input signals for a tuning circuit element in accordance with another embodiment of the present invention.

FIG. 7 schematically illustrates generation of control input signals for a tuning circuit element in accordance with another embodiment of the present invention.

FIG. 8 shows a tuning circuit element in accordance with another embodiment of the present invention.

FIG. 9 schematically shows details of varactors in the tuning circuit element of FIG. 8, in accordance with an embodiment of the present invention.

FIG. 10 shows a tuning circuit element in accordance with another embodiment of the present invention.

The use of the same reference label in different drawings indicates the same or like components.

### DETAILED DESCRIPTION

In the present disclosure, numerous specific details are provided, such as examples of electrical circuits, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

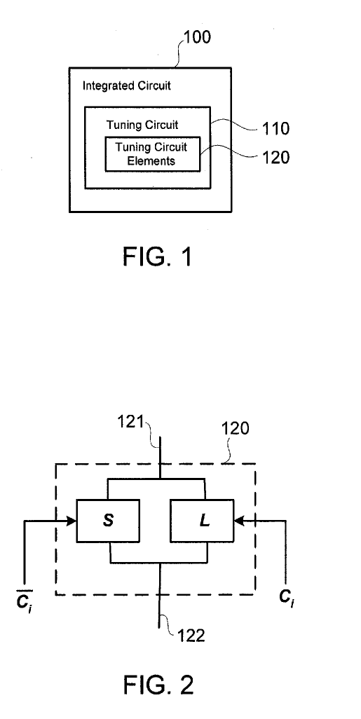

Embodiments of the present invention advantageously allow for fabrication of high resolution tuning circuit elements for use by tuning circuits in a monolithic IC. Such a monolithic IC is shown in FIG. 1, where a tuning circuit 110 is fabricated with one or more tuning circuit elements 120 in a monolithic IC 100. The tuning circuit 110 may comprise an electrical circuit used for frequency tuning, such as a digitally controlled oscillator, for example. A tuning circuit element 120 may comprise one or more circuits used by the tuning circuit 110 for adjusting frequencies. As will be more apparent below, the tuning circuit elements 120 may comprise components and circuits, such as varactors and current sources, for example.

The IC 100 is monolithic in that the tuning circuit 110 and the tuning circuit elements 120 are fabricated on the same substrate. For example, the tuning circuit 110 and the tuning circuit elements 120 may be fabricated on the same semiconductor die. It is to be noted that IC fabrication processes, in general, are known in the art and thus not further described here. Embodiments of the present invention provide tuning circuit elements that may be readily fabricated as part of a monolithic IC.

FIG. 2 schematically shows a tuning circuit element 120 in accordance with an embodiment of the present invention. In the example of FIG. 2, the tuning circuit element 120 includes two sub-element circuits namely, an S-type circuit element (labeled as “S”) and an L-type circuit element (labeled as “L”). The S-type circuit element accepts a single digital control signal input c̅ᵢ, and the L-type circuit element accepts a single digital control signal input cᵢ. The control input signals cᵢ and c̅ᵢ̅ are binary and complementary with each other. In other words, cᵢ is a binary one when c̅ᵢ̅ is a binary zero, and vice versa.

In one embodiment, the S-type circuit element has a circuit value of Sₒₙ when its associated control input signal c̅ᵢ̅ is a binary one, and a circuit value of S_{off} when its associated control input signal c̅ᵢ̅ is a binary zero. An L-type circuit element has a circuit value of Lₒₙ when its associated control input signal cᵢ is a binary one and a circuit value of L_{off} when its associated control input signal cᵢ is a binary zero. The circuit value of the tuning circuit element 120 is the combination of the circuit values of the S-type circuit element and the L-type circuit element. In the example of FIG. 2, the circuit value of the tuning circuit element 120 is the sum of the circuit values of the S-type and L-type circuit elements.

Given that the control input signals cᵢ and c̅ᵢ̅ are binary and complementary, the tuning circuit 120 of FIG. 2 has two possible outputs across the nodes 121 and 122: a first output comprising a combination of Sₒₙ and L_{off} when the control input signal c̅ᵢ̅ is at a first logical value (binary one in this example), and a second output comprising a combination of S_{off} and Lₒₙ when the control input signal c̅ᵢ̅ is at a second logical value (binary zero in this example), the first and second logical values being binary and complementary with each other.

In one embodiment, the circuit values Sₒₙ and Lₒₙ are substantially the same, with Lₒₙ being slightly larger than Sₒₙ. For example, Lₒₙ may be at most 20% larger than Sₒₙ. Similarly, the circuit values S_{off} and L_{off} are substantially the same, with L_{off} being slightly larger than S_{off}, e.g., L_{off} being larger than S_{off} by at most 20%. The smaller the difference between Sₒₙ and Lₒₙ and between S_{off} and L_{off}, the better the resulting tuning resolution. The sum of S_{off} and Lₒₙ is different from the sum of Sₒₙ and L_{off}.

The output of the tuning circuit element 120 may be an electrical property, such as capacitance, resistance, inductance, electrical current etc. For example, the tuning circuit element 120 may provide capacitance when it is configured as a capacitor, resistance when it is configured as a resistor, inductance when it is configured as an inductor, electrical current when it is configured as a current source, and so on. The tuning circuit element 120 may be coupled to a tuning circuit by connecting to the nodes 121 and 122.

As a particular example, the S-type and L-type circuit elements may each comprise a capacitor. In this example, the S-type circuit element provides a capacitance of 1 fF (i.e., 1 femto Farad) when the control signal input c̅ᵢ̅ is a binary one, and a capacitance of 0.2 fF when the control signal input c̅ᵢ̅ is a binary zero. Also in this example, the L-type circuit element provides a capacitance of 1.1 fF when the control input signal cᵢ is a binary one, and a capacitance of 0.25 fF when its associated control input signal cᵢ is a binary zero. The resulting capacitance of the tuning circuit element 120, in this particular example, is 1.3 fF when the control input signal cᵢ is a binary one (i.e., 1.1 fF+0.2 fF) and 1.25 fF when the control input signal cᵢ is a binary zero (i.e., 1 fF+0.25 fF). This provides a resolution of 0.05 fF (i.e., 1.3 fF−1.25 fF).

FIG. 2 shows an example where the tuning circuit element 120 has a single pair of circuit elements, i.e., one S-type circuit element and one L-type circuit element. In general, a tuning circuit element 120 may comprise n S-type circuit elements and n L-type circuit elements. If m out of n control input signals cᵢ are binary one, the sum of the circuit values of all the S-type and L-type circuit elements in the tuning circuit element 120 is

n·(Sₒₙ+L_{off})+m·(Lₒₙ+S_{off}−L_{off}−Sₒₙ) (EQ. 1)

The first term of EQ. 1 (i.e., n(Sₒₙ+L_{off})) is a common term for different m whereas the term enclosed in the parenthesis in the second term (i.e., (Lₒₙ+S_{off}−L_{off}−Sₒₙ)) represents the resolution of the tuning circuit element 120. As can be appreciated, the resulting resolution is equal to the difference of (Lₒₙ+S_{off}) and (L_{off}+Sₒₙ), which is the difference between circuit values of the two possible states of a single circuit element. This difference is subject to fine lithography of a given technology. In other words, the resolution of the tuning circuit element is subject to the minimal increment of a device in a given fabrication process technology rather than the minimum feature size allowable by the fabrication process technology.

It is to be noted that the minimal increment of a particular device is much smaller than the minimum feature size of the device. Therefore, embodiments of the present invention allow for digitally controlled tuning circuit elements with very fine resolution. Since the resolution of the tuning circuit elements is now limited by the minimal increment of a device instead of its minimum feature size, a device with larger size can be used. Advantageously, the larger the size of a circuit element, the less the circuit element varies. Therefore, induced noise power is smaller with larger circuit elements.

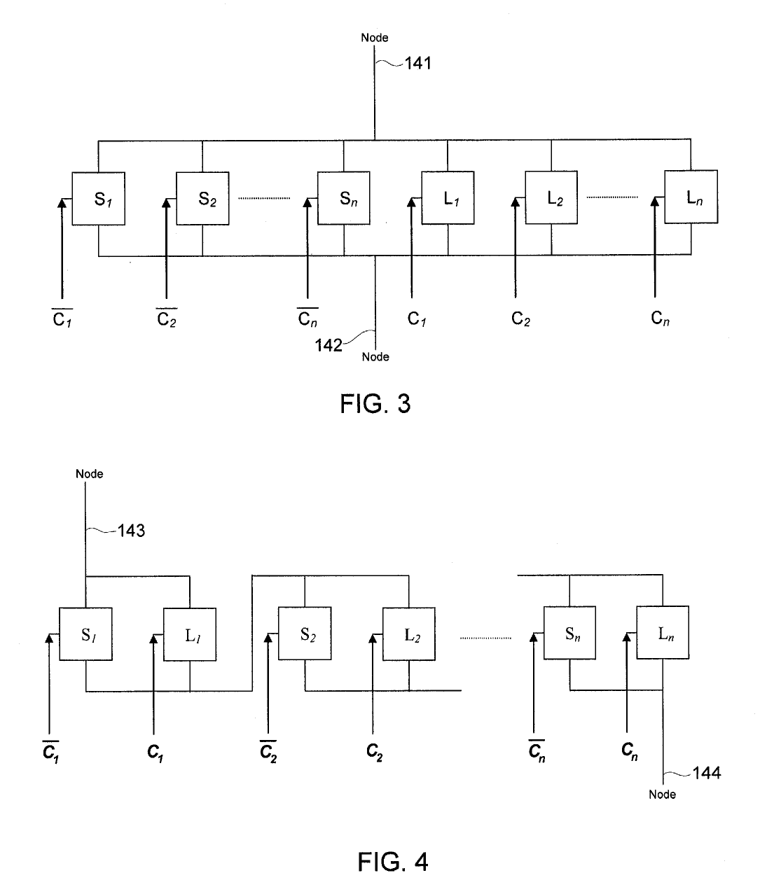

The S-type and L-type circuit elements may be coupled together a variety of ways. FIG. 3 schematically shows a tuning circuit element where there are n pairs of S-type circuit elements and L-type circuit elements that are coupled in parallel. In the example of FIG. 3, there are n S-type circuit elements (i.e., S₁ . . . Sₙ), with each S-type circuit element receiving a corresponding single digital control input signal c̅ᵢ̅ (i.e., c₁ . . . c̅ₙ). Similarly, in the example of FIG. 3, there are n L-type circuit elements (i.e., L₁ . . . Lₙ) with each L-type circuit element receiving a corresponding single digital control input signal cᵢ(i.e., c₁ . . . cₙ). The tuning circuit element of FIG. 3 may be coupled to a tuning circuit by way of nodes 141 and 142. For example, the tuning circuit element of FIG. 3 may be used as a high-resolution capacitor of a tuning circuit. This advantageously allows the tuning circuit to have fine tuning of frequencies.

Pairs of S-type circuit elements and L-type circuit elements may also be coupled together in series as shown in FIG. 4. In the example of FIG. 4, the tuning circuit element includes n pairs of S-type circuit elements and L-type circuit elements in series connection. In the example of FIG. 4, the first pair of circuit elements S₁ and L₁ is serially connected to the second pair of circuit elements S₂ and L₂, which is serially connected to a third pair of circuit elements and so on. The tuning circuit element of FIG. 4 may be coupled to a tuning circuit by way of nodes 143 and 144.

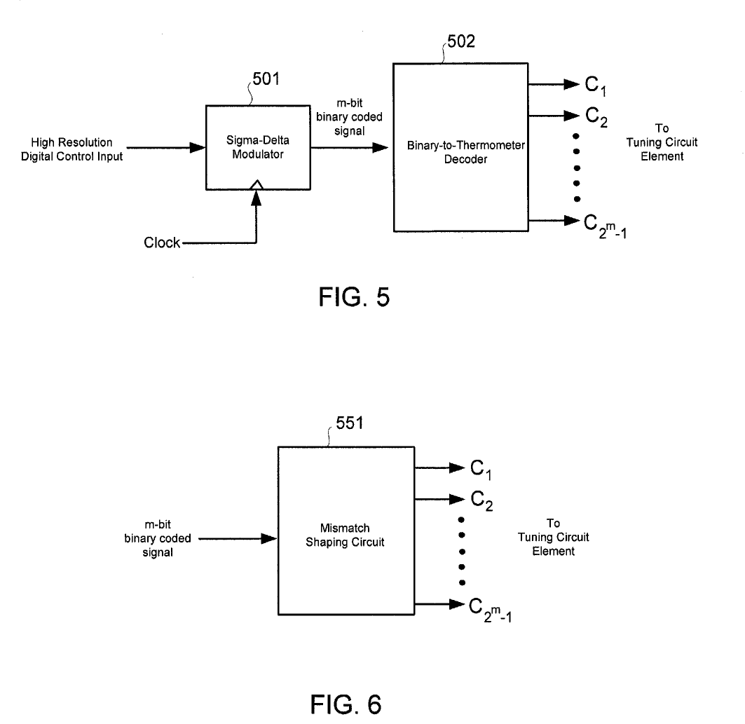

The control input signals c̅ᵢ̅ and cᵢ may be generated a variety of ways without detracting from the merits of the present invention. For example, a control input signal cᵢ may be generated by a tuning circuit to adjust the output of the corresponding tuning circuit element; an inverter may be used to generate the control input signal c̅ᵢ̅ from the control input signal cᵢ. Despite the high resolution provided by the tuning circuit elements of the present invention, there are applications where the resolution of the control input signals far exceeds the resolution of the tuning circuit element. Preferably, in those situations, the resolution of the control input signals are pre-processed to match the resolution of the tuning circuit element with minimum loss to overall tuning resolution. Examples on how this can be achieved are discussed with reference to FIGS. 5-7.

FIG. 5 schematically illustrates generation of control input signals for a tuning circuit element in accordance with an embodiment of the present invention. In the example of FIG. 5, a high-resolution digital control input signal comprises a multi-bit digital signal for controlling a tuning circuit element. A clock-driven sigma-delta modulator 501 receives the high-resolution digital control input signal to generate an m-bit binary coded signal. The sigma-delta modulator 501 may employ a time-averaged mechanism to reduce the resolution of the high-resolution digital control input signal. For example, the sigma-delta modulator 501 may be configured to generate a high-rate m-bit binary coded signal with an average value that is equal to a desired low-rate high-resolution digital control input signal suitable for controlling a tuning circuit element. As shown in FIG. 5, the m-bit binary coded signal output of the sigma-delta modulator 501 may be provided to a binary-to-thermometer decoder 502 to generate control input signals c₁ to c₂_{^{m}}₋₁. Generally speaking, a binary-to-thermometer decoder converts a binary-encoded m-bit signal to a (2^{m}−1)-bit thermometer coded signal. The output of the binary-to-thermometer decoder 502 may be employed as digital control input signals of a tuning circuit element.

FIG. 6 schematically illustrates generation of control input signals for a tuning circuit element in accordance with another embodiment of the present invention. In the example of FIG. 6, a mismatch shaping circuit 551 receives an m-bit binary coded signal to generate control input signals c₁ to c₂_{^{m}}₋₁. The mismatch shaping circuit 551 may be configured to increase linearity and further shape mismatch noise to different frequency bands. The output of the mismatch shaping circuit 551 may be employed as digital control input signals of a tuning circuit element.

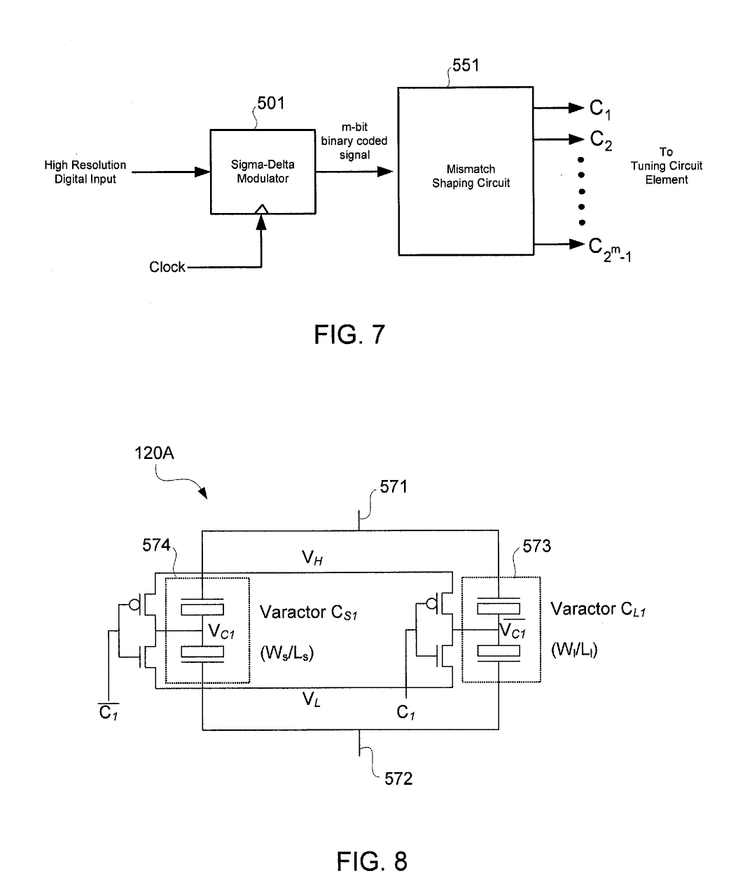

FIG. 7 schematically illustrates generation of control input signals for a tuning circuit element in accordance with another embodiment of the present invention. In the example of FIG. 7, the sigma-delta modulator 501 receives high-resolution digital control input signals to generate an m-bit binary coded signal as in FIG. 5. Unlike in FIG. 5, the m-bit binary coded signal is input to the mismatch shaping circuit 551 in FIG. 7. The output of the mismatch shaping circuit 551 of FIG. 7 is then employed as control input signals of a tuning circuit element.

As can be appreciated, a tuning circuit element in accordance with embodiments of the present invention may be implemented a number of ways without detracting from the merits of the present invention.

FIG. 8 shows a tuning circuit element 120A in accordance with another embodiment of the present invention. The tuning circuit element 120A is a particular embodiment of the tuning circuit element 120 of FIG. 2. The tuning circuit element 120A is an example where the number n pairs of S-type circuit element and L-type circuit element is equal to one. That is, in the example of FIG. 8, there is one S-type circuit element and one L-type circuit element.

In the example of FIG. 8, the S-type circuit element comprises a varactor 574 (also labeled as “Varactor C_{S1}”) and the L-type circuit element comprises a varactor 573 (also labeled as “Varactor C_{L1}”). As before, the S-type circuit element and the L-type circuit element are controlled using digital control input signals c̅₁̅ and c₁, respectively. When the control input signal c₁ is binary one, the varactor 573 has a capacitance of C_{I}_{_{—}}ₒₙ Farad and the varactor 574 Cₛ₁ has the capacitance of Cₛ_{_{—}}_{off} Farad. When the control input signal c₁ is a binary zero, the varactor 573 has a capacitance of C_{I}_{_{—}}_{off} Farad and the varactor 574 has a capacitance of Cₛ_{_{—}}ₒₙ Farad. The control input signal c̅₁̅ generates a control voltage V_{c1} in the varactor 574 and the control input signal c₁ generates a control voltage V̅_̅{̅C̅1̅}̅ in the varactor 573. The capacitance (C_{I}_{_{—}}ₒₙ+Cₛ_{off}) is greater than the capacitance (Cₛ_{_{—}}ₒₙ+C_{I}_{_{—}}_{off}).

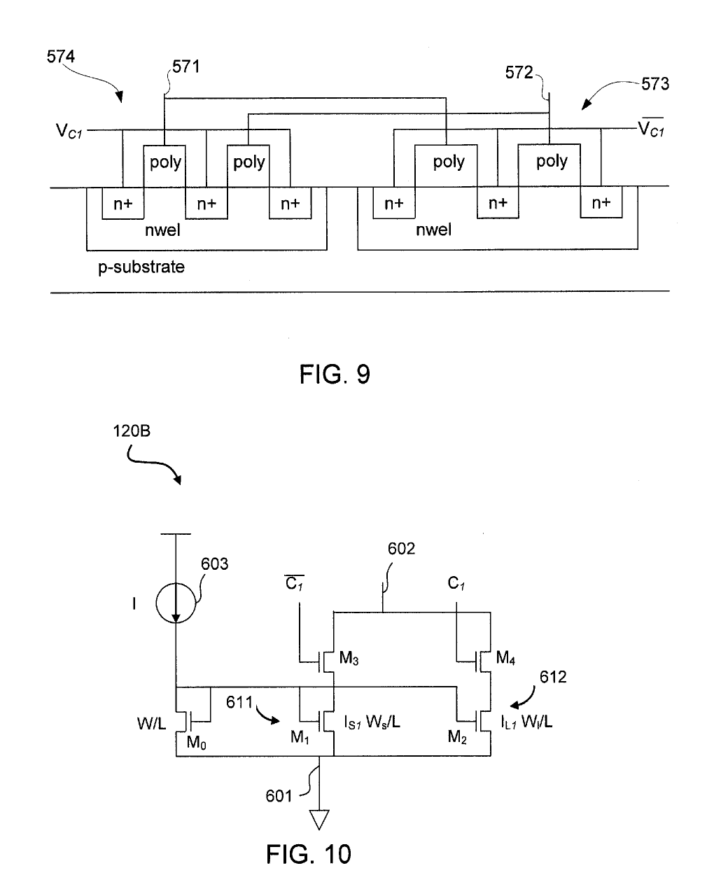

FIG. 9 schematically shows details of the varactors 574 and 573 in accordance with an embodiment of the present invention. In the example of FIG. 9, the varactors 574 and 573 are implemented as MOS transistors fabricated on a P-type silicon substrate. The control voltages V_{c1} and V̅_̅{̅C̅1̅}̅ are applied to n+ doped diffusion regions formed in n-wells to vary capacitance between diffusion regions and corresponding polysilicon gates. The nodes 571 and 572 are connected to the polysilicon gates to allow a tuning circuit to use the variable capacitance to tune frequencies.

Referring back to the example of FIG. 8, the capacitance values of C_{I}_{_{—}}ₒₙ and C_{I}_{_{—}}_{off} are equal to α·(W_{I}·L_{I}) and β·(W_{I}·L_{I}), respectively, where W_{I} is the channel width and L_{I} is the channel length of the varactor 573. In this example, the variables α and β are fixed constants. Similarly, the capacitance values of Cₛ_{_{—}}ₒₙ and Cₛ_{_{—}}_{off} are equal to α·(Wₛ·Lₛ) and β·(Wₛ·Lₛ), respectively, where Wₛ is the channel width and Lₛ is the channel length of the varactor 574. Therefore, the resolution of the tuning circuit element 120A is equal to (α−β)·(W_{I}·L_{I}−Wₛ·Lₛ). For the special case of L_{I}=Lₛ, the resolution is equal to (α−β)·L_{I}·(W_{I}−Wₛ) and limited by the minimal width increment and the minimum channel length of a transistor. For the special case of W_{I}=Wₛ, the resolution is equal to (α−β)·W_{I}·(L_{I}−Lₛ) and limited by the minimum channel width and the minimal channel length increment of a transistor. In marked contrast, the minimum resolution of prior art tuning circuit elements is equal to (α−β)·Wₘᵢₙ·Lₘᵢₙ, where Wₘᵢₙ and Lₘᵢₙ are equal to the minimum width and length of the transistor in a given technology.

FIG. 10 shows a tuning circuit element 120B in accordance with another embodiment of the present invention. The tuning circuit element 120B is a particular embodiment of the tuning circuit element 120 of FIG. 2. The tuning circuit element 120B is another example where the number n pairs of S-type circuit element and L-type circuit element is equal to one. That is, in the example of FIG. 10, there is one S-type circuit element and one L-type circuit element.

The tuning circuit element 120B comprises an array of current sources labeled as 611 and 612. In the example of FIG. 10, the L-type circuit element is the current source 612 (also labeled as “I_{L1}”), which is formed by mirroring a current source 603 by way of a transistor M₀ and a transistor M₂. The control input signal c₁ controls a transistor M₄ to enable or disable current flow through the transistor M₂. Similarly, the S-type circuit element is the current source 611 (also labeled as “I_{S1}”), which is formed by mirroring the current source 603 by way of the transistor M₀ and a transistor M₁. The control input signal c̅₁̅ controls a transistor M₃ to enable or disable current flow through the transistor M₁.

When the control input signal c₁ is a binary one, the current source 612 is ON and supplies an amount of current equal to κ·(W_{I}/L) where W_{I} is the channel width and L is the channel length of the transistor M₂. The variable κ is a constant in this example. The current source 611 is OFF at this time.

When the control signal c₁ is a binary zero, the current source 611 is ON and supplies an amount of current equal to κ·(Wₛ/L) where Wₛ is the channel width and L is the channel length of the transistor M₁. The current source 612 is OFF when the current source 611 is ON. Accordingly, for the same transistor channel length L for transistors M₀, M₁, and M₂, the electrical current resolution of the tuning circuit element 120B is equal to (W_{I}−Wₛ)/L, which is limited by the minimal width increment of the transistors M₁ and M₂ in a given fabrication process technology. This is in marked contrast to conventional approaches where the resolution of the tuning circuit element is limited by the allowable minimum feature size (not size increment).

High resolution tuning circuit elements have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A digitally controlled tuning circuit element for a tuning circuit, the tuning circuit element comprising:
a first circuit element coupled to receive a first digital control input signal, the first circuit element generating a first circuit value when the first digital control input signal is at a first logical value and a second circuit value when the first digital control input signal is at a second logical value, the first and second logical values being binary and complementary with each other;
a second circuit element coupled to receive a second digital control input signal, the second circuit element generating a third circuit value when the second digital control input signal is at the first logical value and a fourth circuit value when the second digital control input signal is at the second logical value, the first and second digital control input signals being binary and complementary with each other; and
wherein a sum of the first circuit value and the fourth circuit value is different from a sum of the second circuit value and the third circuit value.

2. The tuning circuit element of claim 1 wherein the first circuit element and the second circuit element each comprises a varactor.

3. The tuning circuit element of claim 1 wherein the first circuit element and the second circuit element each comprises a current source.

4. The tuning circuit element of claim 1 wherein the third circuit value is greater than the second circuit value by at most 20%.

5. The tuning circuit element of claim 1 wherein the first, second, third, and fourth circuit values comprise capacitance.

6. The tuning circuit element of claim 1 wherein the first digital control input signal is generated by a binary-to-thermometer decoder.

7. The tuning circuit element of claim 6 wherein the binary-to-thermometer decoder generates the first digital control input signal from a binary coded signal generated by a sigma-delta modulator.

8. The tuning circuit element of claim 1 wherein the first digital control input signal is generated by a mismatch shaping circuit.

9. The tuning circuit element of claim 8 wherein the mismatch shaping circuit receives a binary coded signal from a sigma-delta modulator.

10. A method performed by a tuning circuit element in a monolithic integrated circuit, the method comprising:
receiving a first digital control input signal and a second digital control input signal, the first and second digital control input signals being binary and complementary with each other;
generating a first circuit value and a fourth circuit value when the first digital control input signal is at a first logical value, the first circuit value being generated by a first type of circuit element receiving the first digital control input signal, the fourth circuit value being generated by a second type of circuit element receiving the second digital control input signal, the first circuit value and the fourth circuit value being combined as a first output;
generating a second circuit value and a third circuit value when the second digital control input signal is at the first logical value, the second circuit value being generated by the first type of circuit element receiving the first digital control input signal, the third circuit value being generated by the second type of circuit element receiving the second digital control input signal, wherein a sum of the first circuit value and the fourth circuit value is different from a sum of the second circuit value and the third circuit value, the second circuit value and the third circuit value being combined as a second output;
providing the first output but not the second output to a tuning circuit in the monolithic integrated circuit when the first digital control input signal is at the first logical value;
providing the second output but not the first output to the tuning circuit when the first digital control input signal is at a second logical value, the first and second logical values being binary and complementary with each other.

11. The method of claim 10 wherein the first, second, third and fourth circuit values comprise capacitance.

12. The method of claim 10 wherein the first digital control input signal is generated by a binary-to-thermometer decoder.

13. The method of claim 10 wherein the first type and the second type of circuit elements each comprises a varactor.

14. The method of claim 10 wherein the first type and the second type of circuit elements each comprises a current source.

15. An electrical circuit comprising:
a first circuit configured to receive a first digital control input signal and a second digital control input signal, the first digital control input signal and the second digital control input signal being binary and complementary with each other, the first circuit being configured to generate a first output comprising a sum of a first circuit value and a fourth circuit value when the first digital control input signal is at a first logical value and a second output comprising a sum of a second circuit value and a third circuit value when the first digital control input signal is at a second logical value, the first and second logical values being binary and complementary with each other, the sum of the first output being different from the second output;
a tuning circuit configured to use the first output but not the second output to adjust a frequency when the first digital control input signal is at the first logical value and to use the second output but not the first output to adjust the frequency when the first digital control input signal is at the second logical value;
wherein the first circuit is in a monolithic integrated circuit.

16. The electrical circuit of claim 15 further comprising:
a second circuit configured to receive a third digital control input signal and a fourth digital control input signal, the third digital control input signal and the fourth digital control input signal being binary and complementary with each other, the second circuit being configured to generate a third output when the third digital control input signal is at the first logical value and a fourth output when the third digital control input signal is at the second logical value, the third output being different from the fourth output.

17. The electrical circuit of claim 16 wherein the first and second circuits are connected in parallel.

18. The electrical circuit of claim 16 wherein the first and second circuits are connected in series.

19. The electrical circuit of claim 15 wherein the first circuit comprises varactors.
